(19) United States
(12) Patent Application Publication
(10) Pub. No.: US 2013/0129922 A1
(43) Pub. Date: May 23, 2013

(54) BATCH PROCESSING FOR ELECTROMECHANICAL SYSTEMS AND EQUIPMENT FOR SAME

(71) Applicants: Teruo Sasagawa, Los Gatos, CA (US); Leonard Eugene Fennell, Foster City, CA (US)

(72) Inventors: Teruo Sasagawa, Los Gatos, CA (US); Leonard Eugene Fennell, Foster City, CA (US)

(73) Assignee: QUALCOMM MEMS TECHNOLOGIES, INC., San Diego, CA (US)

(21) Appl. No.: 13/301,630

(22) Filed: Nov. 21, 2011

(51) Int. Cl. C23C 16/02; C23F 1/08; C23C 16/44

(52) U.S. Cl. 427/255.7; 427/248.1; 118/719; 156/345.1

(57) ABSTRACT

This disclosure provides systems, methods and apparatus for processing multiple substrates in a batch cluster tool. A batch cluster tool can include a transfer chamber, an etch process chamber, and one or both of an ALD process chamber and an SAM process chamber. Multiple substrates are transferred from a transfer chamber into an etch chamber. The substrates are exposed to a vapor phase etchant. The substrates can then transferred to an atomic layer deposition (ALD) chamber and exposed to vapor phase reactants to form a thin film on the substrates by ALD. The substrates can be transferred either from the etch process chamber or the ALD chamber to a third chamber and exposed to vapor phase reactants to form a self-assembled monolayer (SAM) on the substrates.

### TECHNICAL FIELD

This disclosure relates to electromechanical systems.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Typically one of the last fabrication processes before packaging an electromechanical system apparatus is the removal of a sacrificial layer from underneath a movable layer to define the cavity through which the movable layer can move. The removal of the sacrificial layer is often referred to as a release etch. After release, the device is vulnerable and sensitive to damage during subsequent handling and processing.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of forming a device. The method includes transferring a batch of substrates from a transfer chamber of a batch cluster tool into an etch chamber of the batch cluster tool. The substrates are exposed to a vapor phase etchant, and after exposing the substrates to a vapor phase etchant, at least one of the following are performed: (1) transferring the substrates through the transfer chamber and into an atomic layer deposition (ALD) chamber and exposing the substrates to vapor phase reactants to form a thin film on the substrates by ALD; and (2) transferring the substrates through the transfer chamber and into a third chamber and exposing the substrates to vapor phase reactants to form a self-assembled monolayer (SAM) on the substrates.

In some implementations the thin film is formed on the substrates by ALD and the SAM is formed on the substrates. In some implementations transferring a batch includes sequential single substrate transfer or a batch transfer. In some implementations the processing pressure of at least one of the etch, ALD, and SAM processes is different from the transfer pressure.

One innovative aspect of the subject matter described in this disclosure can be implemented in a method for forming an electromechanical systems device. The method includes removing sacrificial layers to create gaps between movable electrodes and stationary electrodes of electromechanical devices on multiple substrates in a first batch process chamber of a cluster tool. At least one of the following are performed: (1) depositing atomic layer deposition (ALD) layers within the gaps of the substrates in a second batch process chamber of the cluster tool by atomic layer deposition; and (2) depositing self-assembled monolayers (SAMs) within the gaps of the substrates in a third batch process chamber of the cluster tool.

In some implementations the ALD layers are formed within the gaps of the substrates and the self-assembled monolayers (SAMs) are deposited over the ALD layers within the gaps of the substrates in a third batch process chamber of the cluster tool. In some implementations each of removing the sacrificial layers, depositing ALD layers, and depositing the SAMs are conducted at pressures greater than 10⁻² Torr while a transfer chamber of the cluster tool connected to each of the process chambers is maintained at a pressure less than 10⁻⁴ Torr when transferring substrates among the transfer chamber and each of the processing chambers. In some implementations removing the sacrificial layers includes providing XeF₂ to the first batch process chamber of the cluster tool while maintaining a pressure in the first batch process chamber of the cluster tool between about 0.1 and about 5 Torr. In some implementations depositing ALD layers includes providing trimethyl aluminum (TMA) and water in alternate and sequential pulses to the second batch process chamber of the cluster tool to deposit aluminum oxide ALD layers. In some implementations depositing SAMs includes providing n-decyltrichlorosilane to the third batch process chamber of the cluster tool. ALD and SAM deposition can include establishing pressure in the respective batch process chambers between about 100 mTorr and about 1 Torr.

One innovative aspect of the subject matter described in this disclosure can be implemented in an apparatus for processing electromechanical systems devices. The apparatus includes a first processing chamber configured to process multiple substrates, wherein the first processing chamber is in fluid communication with an etchant source including a fluorine based etchant. The apparatus further includes one or more of the following: (1) a second processing chamber configured to process multiple substrates, wherein the second processing chamber is in fluid communication with a first source including an oxidizing source and a second source including one of a semiconductor and a metal source; and (2) a third processing chamber configured to process multiple substrates, wherein the third processing chamber is in fluid communication with an organic source chemical. The apparatus also includes a transfer chamber selectively communicating with each of the first, and second or third processing chambers, wherein the transfer chamber includes a robot configured to transfer substrates among the transfer chamber and first, and second or third processing chambers. In some implementations the apparatus includes both the second processing chamber and the third processing chamber.

In some implementations the apparatus includes the second processing chamber and the third processing chamber. In some implementations the apparatus includes a control system in communication with the second processing chamber for alternatingly switching between the first source and the second source. In some implementations the batch cluster tool is configured to handle rectangular substrates having an area greater than the area of rectangular substrate with dimensions of about 370 mm by about 470 mm. In some implementations the fluorine based etchant is XeF₂, the metal source is trimethyl aluminum, the oxidizing source is water, and the organic source chemical is n-decyltrichlorosilane.

One innovative aspect of the subject matter described in this disclosure can be implemented in a batch cluster tool for processing electromechanical systems devices. The batch cluster tool includes a first processing chamber configured to process multiple substrates, including means for removing sacrificial layers from the substrates. The batch cluster tool also includes one or more of the following: (1) a second processing chamber configured to process multiple substrates, including means for forming an ALD layer on the substrates; and (2) a third processing chamber configured to process multiple substrates, including means for forming a self-assembled monolayer on the substrates. The batch cluster tool also includes a transfer chamber capable of selectively communicating substrates among the first, and second or third processing chamber, including means for transferring substrates between chambers of the first, second, and third processing chambers.

In some implementations the apparatus includes both the second processing chamber and the third processing chamber.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8F show examples of cross-sectional schematic illustrations of various stages in a method of making an interferometric modulator.

FIG. 9 shows an example of a flow diagram illustrating a method for processing a batch of substrates.

FIG. 10 shows an example of a flow diagram illustrating a method for processing a batch of substrates.

FIG. 11 is a schematic cross section of an example of an apparatus for batch processing.

FIG. 12 is a schematic plan view of one example of an apparatus for batch processing.

FIG. 13 is a schematic plan view of another example of an apparatus for batch processing.

FIG. 14 is a schematic plan view of another example of an apparatus for batch processing.

FIGS. 15A-15C show schematic cross sections of a batch process chamber useful for batch cluster tools like those of FIGS. 11-14.

FIG. 16 shows a schematic cross section of an example of a batch process chamber, having connections to three different gas delivery systems configured for etching, atomic layer deposition (ALD) and self-assembled monolayer (SAM) deposition.

FIG. 17A is a schematic illustration of an example of a batch process chamber configured for release etching.

FIG. 17B is a schematic illustration of an example of a batch process chamber configured for ALD.

FIG. 17C is a schematic illustration of an example of a batch process chamber configured for SAM deposition.

FIGS. 18A and 18B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (such as a video) or stationary (such as a still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (such as display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Processing electromechanical systems devices can include a release etch process to etch a portion of each device to form an internal cavity in the device. After release, an antistiction layer can be formed in the cavity to reduce stiction in the device. The antistiction layer can include a layer formed by atomic layer deposition (ALD). In some implementations, additional deposition of a self-assembled monolayer (SAM) formed on top of the ALD layer can provide even further anti-stiction properties over an ALD layer alone. In some implementations, the SAM layer can also be formed over an already-existing layer (such as an etch stop layer) in the device, in which case a SAM anti-stiction layer may be formed after release without an ALD process being used. Each of the release etch, deposition of the ALD layer, and deposition of the SAM can be integrated into a cluster tool with batch process chambers.

Particular implementations of the subject matter described in this disclosure can be implemented to realize one or more of the following potential advantages. The use of batch reactors to process multiple substrates can lower the production costs by increasing the throughput of substrates (that is, substrates processed per hour) and limit exposure to contaminants for sensitive post-release devices. Furthermore, precautions such as controlled relative pressures among a transfer chamber and attached separate processing chambers can decrease the risk for contamination of the substrate between processes and cross contamination of the different processing gases used for the etch/release, ALD layer formation, and SAM formation. In some implementations the transfer chamber and attached separate processing chambers can reduce risk for contamination of the substrate by using a low vacuum pressure in the transfer chamber and in the process chambers after processing and prior to, and during, substrate transfer. Lower impurities in the device cavity can result in improved electrical properties and device performance and stability.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

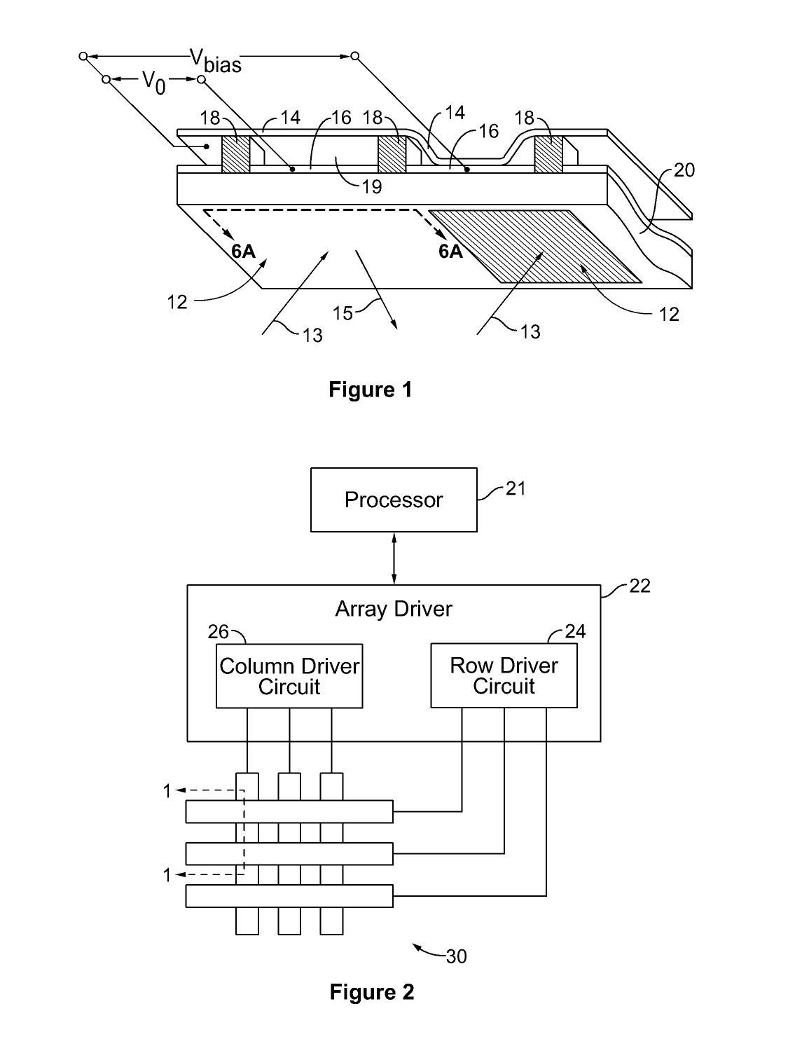

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, for example, to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (such as portions of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

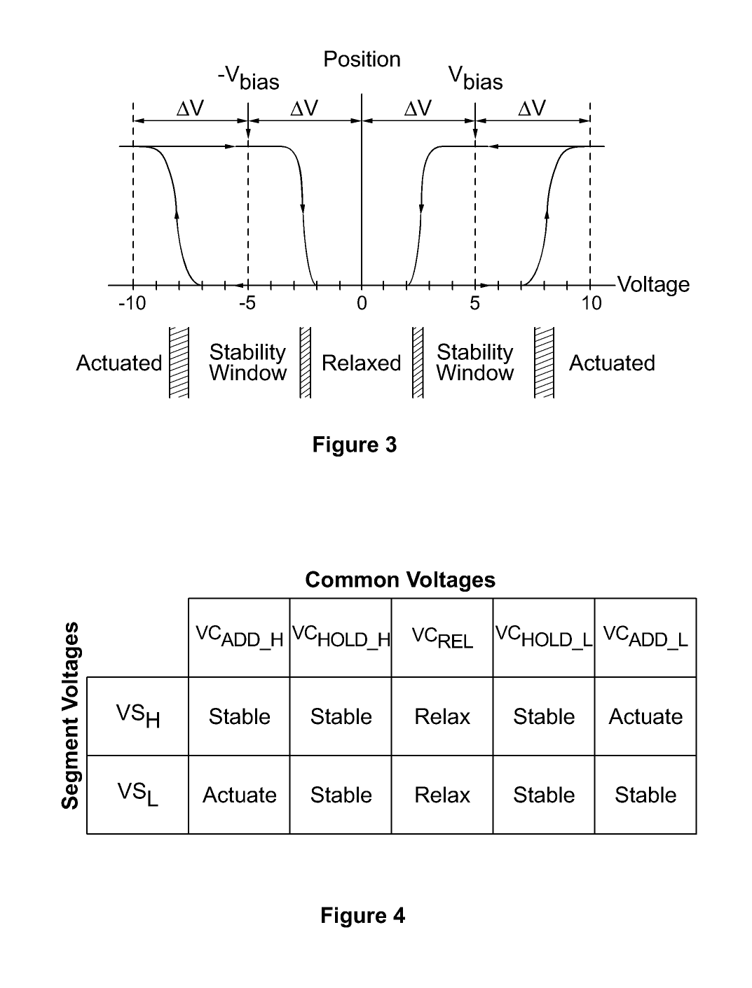

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

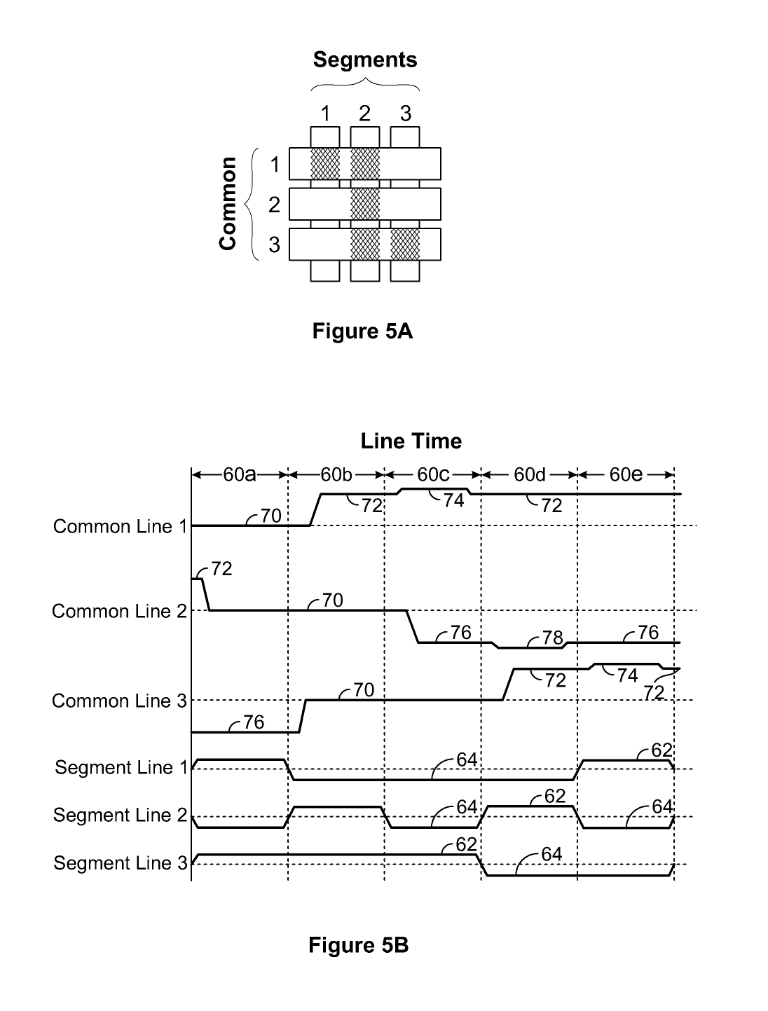

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, in this example, the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

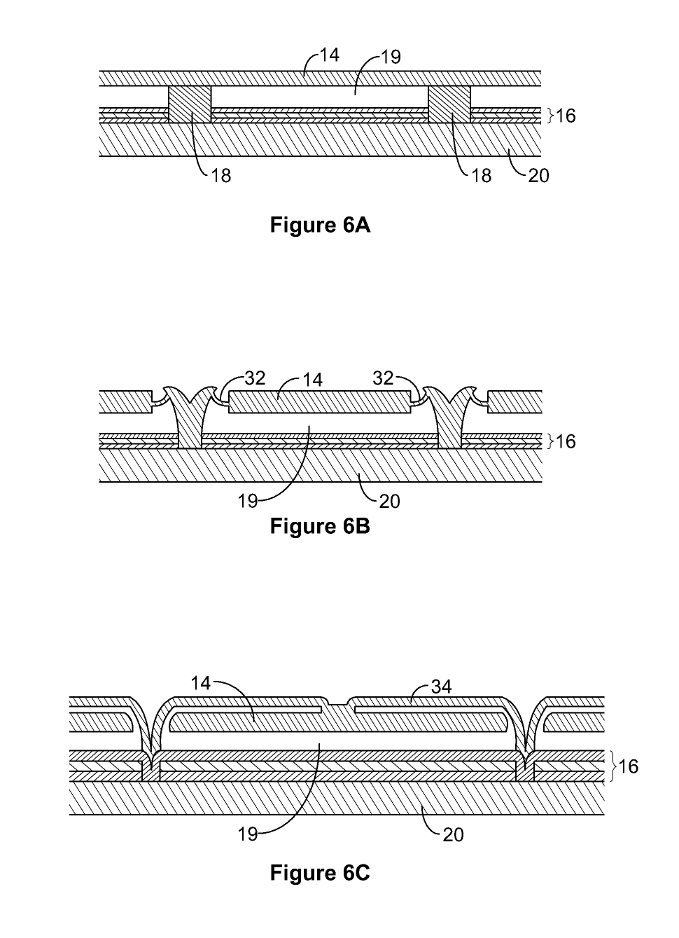

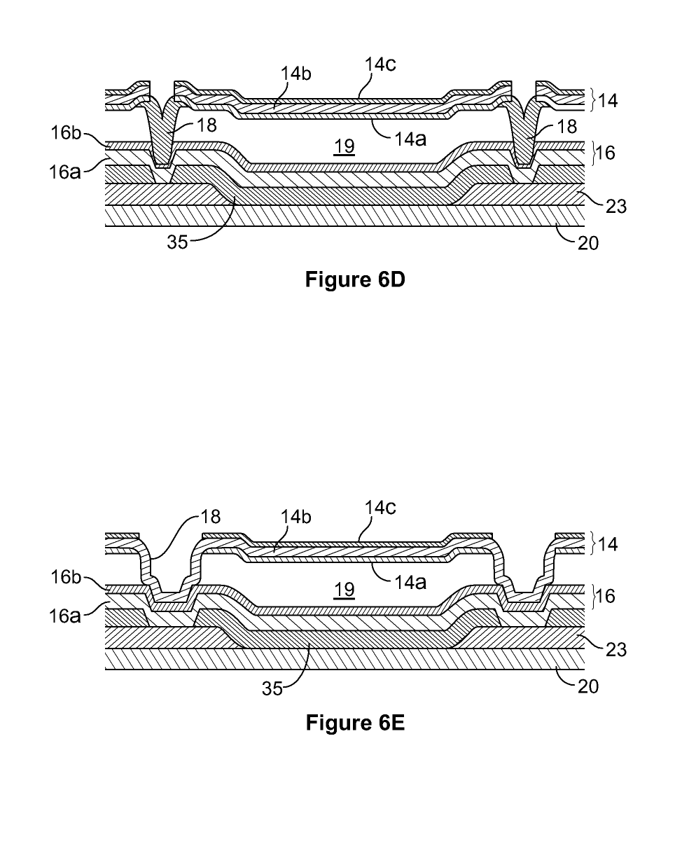

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In this example, the movable electrode and the mechanical layer are one and the same. In FIG. 6B, the movable reflective layer 14 of each IMOD is generally square or rectangular in shape and attached to supports 18 at or near the corners, on tethers 32. The mechanical layer and the movable electrode can also be one and the same in this example. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as supports or support posts 18. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another. The deformable layer 34 can also be referred to as a mechanical layer. Either the deformable layer 34 or the reflective layer 14 could be considered movable layers.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiOₓN_{y}) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under support posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an optical cavity layer, and an Al alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the Al alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes or conductor(s) in the optical stack 16 (such as the absorber layer 16a) from the conductive layers in the black mask 23.

FIG. 6E shows another example of an IMOD, where the movable reflective layer 14 is self supporting. In contrast with FIG. 6D, the implementation of FIG. 6E does not include separately formed support posts. Instead, the movable reflective layer 14 contacts the underlying optical stack 16 at multiple locations to create integrated supports 18, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In the examples of FIGS. 6D and 6E, the entire movable reflective layer 14 or any one or a subset of its sub-layers 14a, 14b and 14c could be considered a mechanical layer or a movable layer. In some implementations, the optical absorber 16a is an order of magnitude (ten times or more) thinner than the movable reflective layer 14. In some implementations, optical absorber 16a is thinner than reflective sub-layer 14a. In some implementations, the optical absorber 16a can serve as a stationary electrode and/or as a partially reflective layer.

In implementations such as those shown in FIGS. 6A-6E, the IMODs function as direct-view devices, in which images are viewed from the front side of the transparent substrate 20, i.e., the side opposite to that upon which the modulator is formed. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

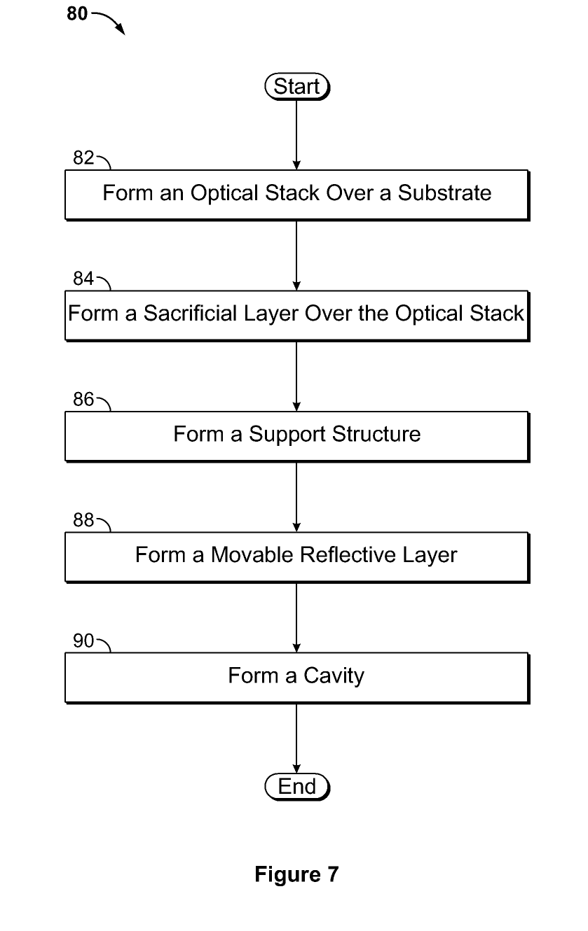

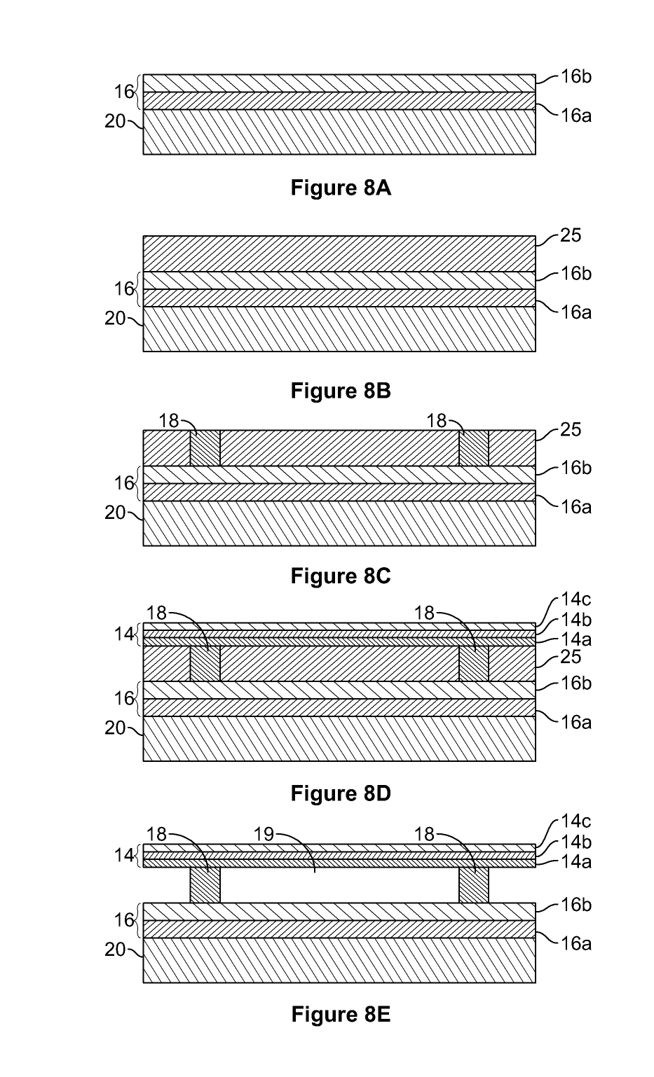

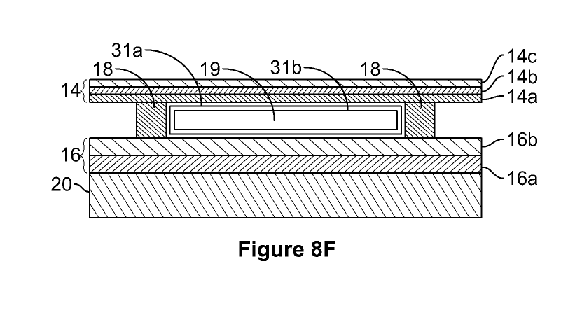

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6A-6E. The manufacture of an electromechanical systems device can also include other blocks not shown in FIG. 7. With reference to FIGS. 1, 6A-6E, and 7, the process 80 begins at block 82 with the formation of the optical stack 16 over the substrate 20. The optical stack 16 includes a lower stationary electrode. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. In non-optical implementations, a stationary electrode can be formed without regard for optical properties. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (such as one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators illustrated in FIGS. 1 and 6A-6E. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material, such as molybdenum (Mo) or amorphous silicon (a-Si), in a thickness selected to provide, after subsequent removal, a gap or cavity 19 (see also FIGS. 1, 6A-6E, and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18 as, illustrated in FIGS. 1, 6A, 6D, 6E and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIGS. 1, 6A-6E, and 8D. The movable reflective layer 14 may be formed by employing one or more deposition processes including, for example, reflective layer (such as Al, Al alloy, or other reflective layer) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b and 14c as shown in FIG. 8D. In some implementations, one or more of the sub-layers, such as sub-layers 14a and 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6A-6E, and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD, and the sacrificial material removal at block 90 may be referred to as a “release etch.”

As shown in FIG. 8F, after release etching defines the cavity, at least the reflective layer 14a and top of the optical stack 16, and in the illustrated implementation all interior surfaces of the cavity 19, can be coated with an antistiction layer. The illustrated antistiction layer includes an ALD layer 31a, formed by atomic layer deposition (ALD), and a self-assembled monolayer (SAM) as described below. It will be understood that antistiction properties can be obtained with one or both of the ALD layer and the SAM. For implementations in which both are employed, the ALD layer 31a can serve as a seed layer for forming the SAM thereover.

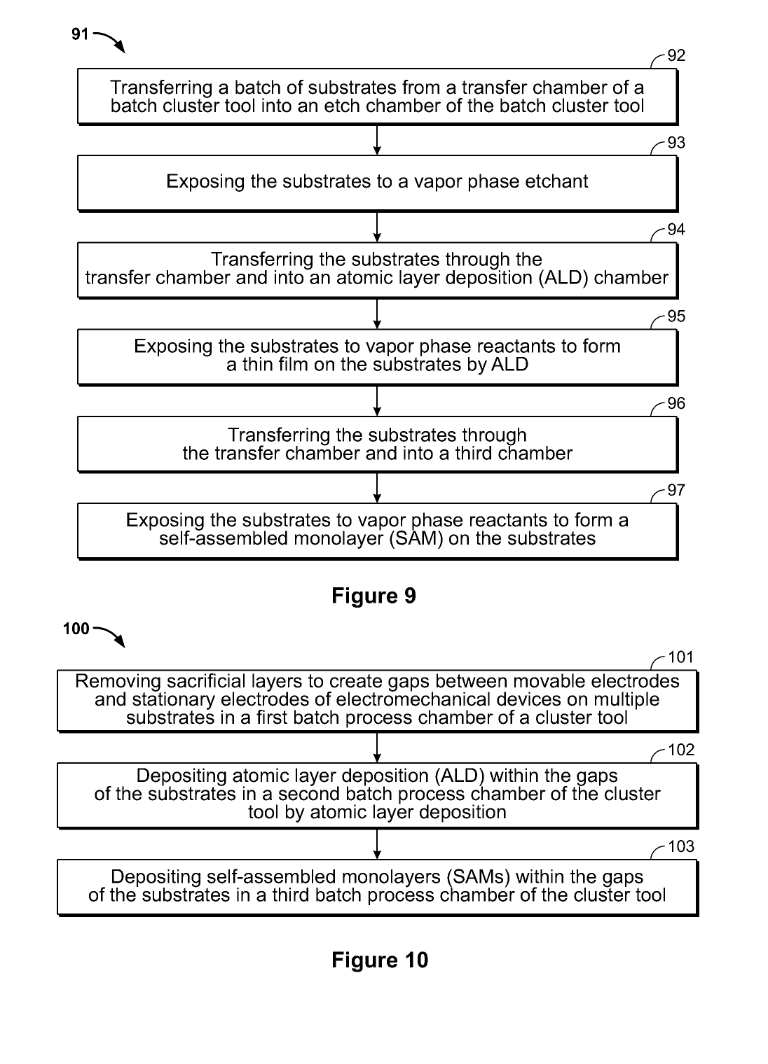

FIG. 9 shows an example of a flow diagram illustrating a method 91 for processing a batch of substrates. In some implementations the method 91 includes at block 92 transferring a batch of substrates from a transfer chamber of a batch cluster tool into an etch chamber of the batch cluster tool. At block 93, the substrates are exposed to a vapor phase etchant. In some implementations, a sacrificial layer is etched in the etch chamber to leave a cavity between electrodes of an electromechanical systems device. At block 94, the substrates are transferred from the etch chamber through the transfer chamber and into an atomic layer deposition (ALD) chamber. At block 95, the substrates are exposed to vapor phase reactants to form a thin film on the substrates by ALD. At block 96, the substrates are transferred from the ALD chamber through the transfer chamber and into a third chamber. At block 97, the substrates are exposed to vapor phase reactants to form a self-assembled monolayer (SAM) on the substrates. In some implementations the method includes blocks 92, 93, 94, and 95 to etch the substrates and form a thin film by ALD on the substrates in the cluster tool, without a subsequent SAM deposition. In some implementations the method includes blocks 92, 93, 96, and 97 to etch the substrates and form a SAM on the substrates in the cluster tool, without an intervening ALD process.

As noted above, FIG. 8F shows an example of an IMOD having the cavity 19 with the ALD layer 31a and the SAM layer 31b formed within the cavity 19. The vapor phase deposition reactants can reach the interior surfaces of the cavity 19 by the same paths that the release etch vapors follow, such as etch holes (not shown) in the reflective movable layer 14, and laterally between supports 18. Although not illustrated, one having ordinary skill in the art will recognize that the ALD and/or SAM depositions can also leave ALD and SAM layers on outer surfaces of the device, such as the upper surface of the conductive layer 14c.

FIG. 10 shows an example of a flow diagram illustrating a method for processing a batch of substrates. In some implementations a method 100 for forming an electromechanical systems device is provided. The method 100 includes at block 101 removing sacrificial layers to create gaps between movable electrodes and stationary electrodes of electromechanical devices on multiple substrates in a first batch process chamber of a cluster tool. At block 102, atomic layer deposition (ALD) layers can be deposited within the gaps of the substrates in a second batch process chamber of the cluster tool by ALD. At block 103, self-assembled monolayers (SAMs) can be deposited within the gaps of the substrates in a third batch process chamber of the cluster tool 73. In some implementations, blocks 101 and 102 are performed to form an ALD layer within the gaps and no SAM is formed, such that the ALD layer is exposed to the cavity on both electrode surfaces. In some implementations, blocks 101 and 103 are performed to form an SAM layer within the gaps without an underlying ALD layer. In some implementations the SAM layer can be formed on an aluminum oxide etch stop layer within the cavity of the substrate.

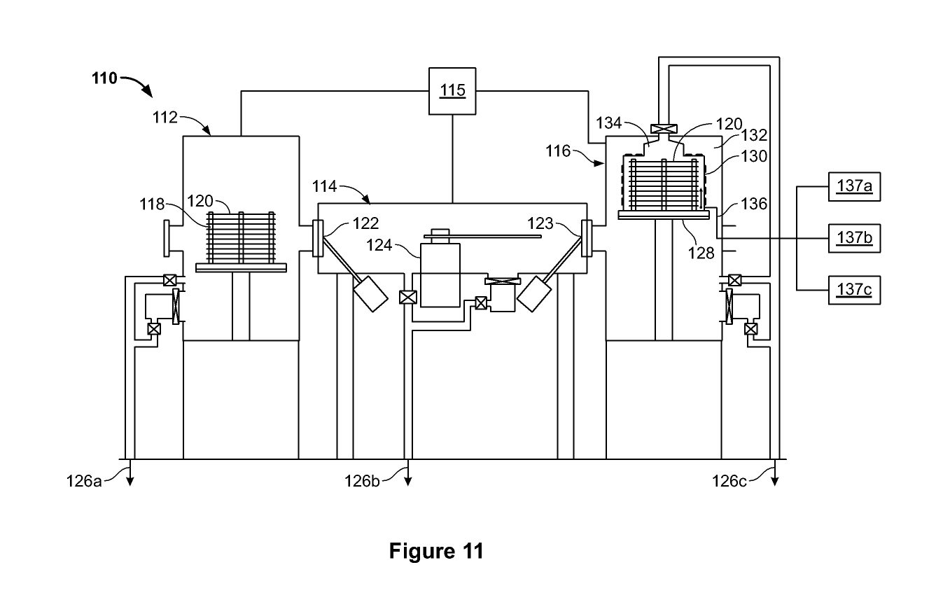

FIG. 11 is a schematic cross section of an example of an apparatus 110 for batch processing. The batch cluster tool 110 includes a load lock chamber 112, a transfer chamber 114, and one or more process chambers 116. The load lock chamber 112 is configured to handle a boat or rack 118 or otherwise configured to handle multiple substrates 120. The load lock chamber 112 can be configured to receive a loaded cassette of substrates from an outside loading platform (not shown). The substrates 120 can be transferred from the load lock chamber 112 through a door 122 into the transfer chamber 114 using a robot 124. The transfer chamber 114 is in selective communication with the load lock chamber 112 and one or more process chambers 116. The transfer chamber 114 is in selective communication with the process chamber 116 when a door 123, such as a gate valve, is open. The transfer chamber 114 is in selective communication with the load lock chamber 112 when the door 122, such as a gate valve, is open. The robot 124 is configured to transfer one or more substrates 120 among the transfer chamber 114, the load lock chamber 112 and the one or more process chambers 116. The process chamber 116 is configured with a platform 128 configured to hold a boat 118 with multiple substrates 120. The platform 128 is provided with an indexing elevator mechanism, capable of moving up and down to facilitate the transfer of substrates 120 through the door 123, and the load lock chamber 112 can be provided with a similar indexing mechanism. The process chamber 116 has an internal volume 132. The platform 128 is configured to engage with a reactor shell 130 to form a reaction space volume 134 within the process chamber 116. The reaction space volume 134 is separate from the internal volume 132 of the process chamber 116 when the platform 128 is engaged with the reactor shell 130 and can form an airtight seal. The reaction space volume 134 is in fluid communication through one or more reactant inlet(s) 136 with one or more reactant sources 137a, 137b, and 137c. The load lock chamber 112, transfer chamber 114, and process chamber 116 are in fluid communication with exhaust lines 126a, 126b, and 126c, respectively, which can be connected to one or more vacuum pump(s) to reduce the pressure in the load lock chamber 112, transfer chamber 114, and process chamber 116. The process chamber 116 and reaction space volume 134 can be configured to perform various processes.

The batch cluster tool 110 can be controlled by a controller 115 configured to control the various functions of the load lock chamber 112, the transfer chamber 114, and the process chamber 116, to perform the desired wafer handling, reactant supply, process pressures, and processes. In some implementations the controller 115 includes a memory and a processor and is configured or programmed to perform the processes illustrated in FIGS. 9 and 10. In some implementations the controller 115 is configured to control the vacuum pumps connected to 126a, 126b, and 126c, respectively. In some implementations, the controller 115 is a master controller that controls subcontrollers for individual chambers, devices or groups of devices in the cluster tool 110.

In some implementations the reactant sources 137a, 137b, and 137c are gas delivery systems or subsystems configured to contain, meter and deliver in the vapor phase reactants for the release etch, ALD layer deposition, and SAM deposition.

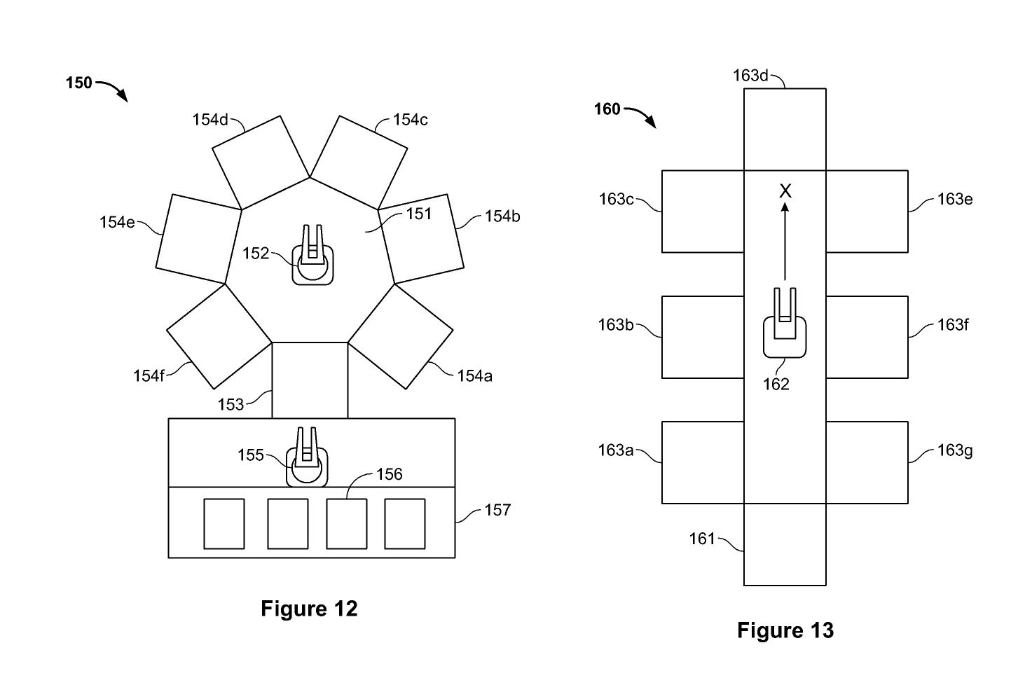

FIG. 12 is a schematic plan view of one example of an apparatus for batch processing. FIG. 12 is a schematic plan view of a batch cluster tool 150. The batch cluster tool 150 includes a transfer chamber 151, a transfer robot 152, a load lock chamber 153, and multiple processing chambers 154a-154f (six shown). FIG. 12 also illustrates a second transfer robot 155 adjacent to a cassette station 157 including multiple cassettes 156, each configured to hold multiple substrates. The second transfer robot 155 can transfer individual substrates or an entire cassette of substrates into or out of the cassette station. The transfer robot 152 is configured to rotate and extend to reach into the internal spaces of the load lock chamber 153 and process chambers 154a-154f to move one or more substrates into and out of the load lock chamber 153 and process chambers 154a-154f. The process chambers 154a-154f can be configured to carry out one or more processes on the substrates. For example, each of the process chambers can be configured to carry out one of or all of the release etch, deposition of the ALD layer, and deposition of the SAM. Tables 1 and 2 below illustrate examples of various configurations for the different process chambers 154a-154f, with an X indicating capability (configuration and plumbing) of performing the indicated process.

FIG. 13 is a schematic plan view of another example of an apparatus for batch processing. FIG. 13 illustrates a batch cluster tool 160 configured differently from FIG. 12. The batch cluster tool 160 includes a load lock chamber 161, a transfer robot 162, and multiple process chambers 163a-163g (seven shown). The transfer robot 162 is configured to move horizontally in the direction between the load lock chamber 161 and process chamber 163d. The transfer robot 162 is also configured to rotate and extend to reach into the internal spaces of the load lock chamber 161 and process chambers 163a-163g to move one or more substrates individually and sequentially one at a time into and out of the load lock chamber 161 and process chambers 163a-163g. In some implementations the robot could have multiple paddles or end effectors to transfer multiple substrates at a time. In some implementations the robot could transfer racks or boats among chambers. The process chambers 163a-163g can be configured to carry out one or more processes on the substrates. For example, each of the process chambers can be configured to carry out one of or all of the release etch, deposition of the ALD layer, and deposition of the SAM. Tables 1 and 2 illustrate examples of various configurations for the different process chambers 163a-163g, with an X indicating capability (configuration and plumbing) of performing the indicated process.

TABLE 1

| Process Chamber | Release/Etch | ALD | SAM |
|---|---|---|---|
| 154a, 163a | X | X | X |
| 154b, 163b | X | X | X |
| 154c, 163c | X | X | X |
| 154d, 163d | X | X | X |
| 154e, 163e | X | X | X |
| 154f, 163f | X | X | X |
| 163g | X | X | X |

TABLE 2

| Process Chamber | Release/Etch | ALD | SAM |
|---|---|---|---|
| 154a, 163a | X | | |
| 154b, 163b | | X | |
| 154c, 163c | | | X |
| 154d, 163d | X | | |
| 154e, 163e | | X | |
| 154f, 163f | | | X |
| 163g | X | X | X |

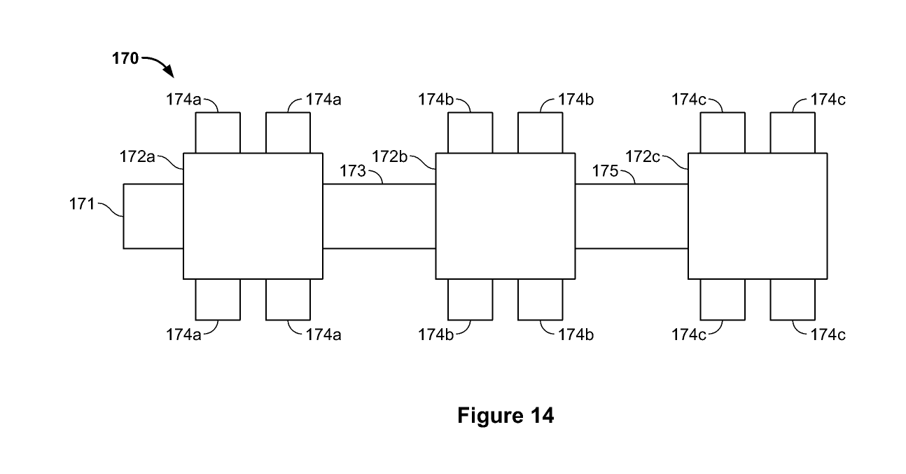

FIG. 14 is a schematic plan view of another example of an apparatus for batch processing. The batch cluster tool 170 includes a load lock chamber 171 and multiple process chambers 174a, 174b and 174c. The batch cluster tool includes transfer chambers 172a, 172b and 172c. The batch cluster tool includes transfer corridors 173 and 175. Substrates can be transferred from the load lock chamber 171 into the first transfer chamber 172a. Substrates can be transferred from the first transfer chamber 172a into the first process chambers 174a. Multiple substrates can be processed simultaneously in each of the first process chambers 174a. After processing multiple substrates in parallel or in staggered fashion, the substrates can be transferred from the first process chambers 174a to the first transfer chamber 172a. Multiple substrates can be transferred from the first transfer chamber 172a through the first transfer corridor 173 to the second transfer chamber 172b. Multiple substrates can be transferred from the second transfer chamber 172b to the second process chambers 174b for processing. After processing multiple substrates in parallel or in staggered fashion, the substrates can be transferred from the second process chambers 174b to the second transfer chamber 172b. Multiple substrates can be transferred from the second transfer chamber 172b through the second transfer corridor 175 to the third transfer chamber 172c. Multiple substrates can be transferred from the third transfer chamber 172c to the third process chambers 174c for processing. In some implementations each of the transfer chambers 172a, 172b, 172c, 173 and 175 can have a transfer robot (not shown). The process chambers 174a, 174b and 174c can be configured to carry out one or more processes on the substrates. For example, each of the first process chambers 174a can be configured to carry out the release etch, each of the second process chambers 174b can be configured to carry out deposition of the ALD layer, and each of the third process chambers 174c can be configured to conduct deposition of the SAM. In some implementations the transfer corridors 173 and 175 are maintained at a lower pressure than the transfer chambers 172a, 172b and 172c to decrease the diffusion of process gases between the different processes and cross-contamination. Staggering processing within the multiple process chambers 172a, 172b or 172c of each stage can be more efficient than parallel processing to stagger the load on the transfer robots.

The process chambers in the batch cluster tool can be configured to perform different deposition processes. For example, the batch cluster tool can have process chambers configured for the etch/release, configured for the formation of an ALD layer, and configured for the formation of a SAM layer. The cluster tool can have one or more controller(s) programmed for performing each of the release, formation of an ALD layer, and formation of a SAM layer in the various process chambers. For example, a batch cluster tool with six processing chambers can include two process chambers configured for each of the etch, ALD layer formation, and SAM layer formation.

After the etch and release the processed substrates are delicate and sensitive to contamination. In some implementations cross contamination of process gases between the different processes is minimized. In some implementations the cluster tool provides minimal movement of process gases between different processes after the release. In some implementations relative pressures are chosen for the transfer chamber, process chambers, and reaction spaces to minimize cross-contamination among the different chemicals for the release, ALD process, and SAM formation.

In some implementations, the different process chambers can be arranged to minimize the transfer time of the substrates between the different processing chambers.

In some implementations the reaction spaces and/or process chambers are purged after processing the substrates and before opening the door between the process chamber and transfer chamber to minimize contamination between the different process chambers and process gases.

In some implementations transferring the substrate can include batch transfer of multiple substrates or an entire rack or boat containing multiple substrates. In some implementations transferring the substrate can include sequentially transferring individual substrates between the transfer chamber and the processing chambers. In some implementations the robot could have multiple paddles or end effectors to transfer multiple substrates at a time. In some implementations the robot could transfer racks or boats among chambers.

In some implementations a robot is used to transfer the substrates or racks between chambers. In some implementations the transfer robot can rotate and extend horizontally to move substrates or racks (such as boats) into or out of a process chamber or load lock chamber.

Different types of substrates can be transferred by the robot and accommodated by the racks. In some implementations rectangular substrates are used. In some implementations circular substrates are used. In some implementations glass substrates are used. In some implementations glass substrates for displays are used. In some implementations glass substrates for EMS displays are used. In some implementations glass substrates are used for IMOD displays. In some implementations the cluster tool and transfer robot are configured to handle G2.5 rectangular substrates with dimensions of about 370 mm by about 470 mm. In some implementations the cluster tool and transfer robot are configured to handle G4.5 rectangular substrates with dimensions of about 730 mm by about 920 mm. In some implementations the cluster tool and transfer robot are configured to handle G11 rectangular substrates with dimensions of about 3.3 m by about 3.1 m.

In some implementations the process chambers are configured to process five or more substrates at the same time. In some implementations the process chambers are configured to process from about 5 substrates to about 25 substrates. In some implementations more than 25 substrates can be processed simultaneously in the process chambers.

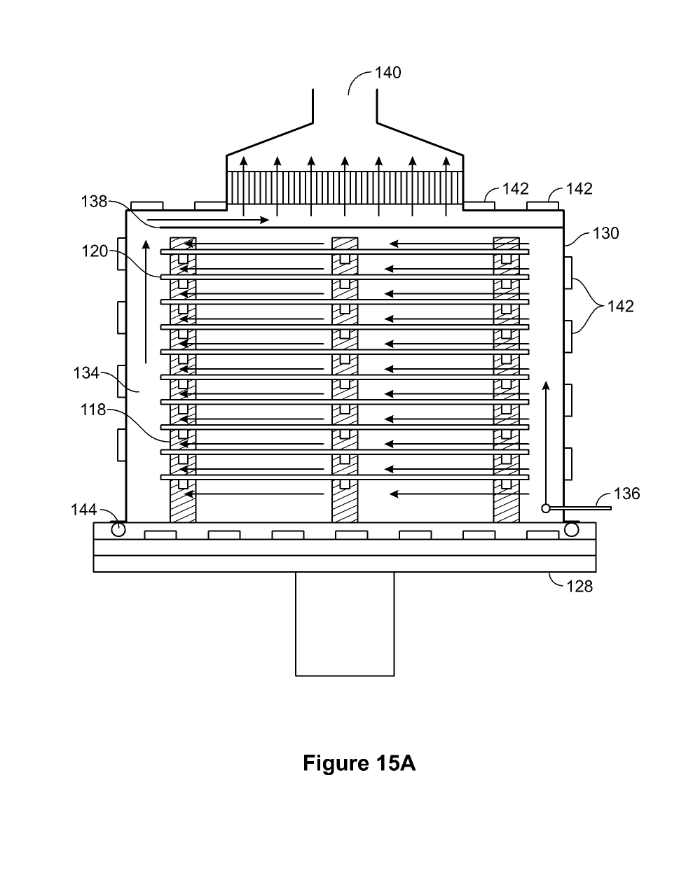

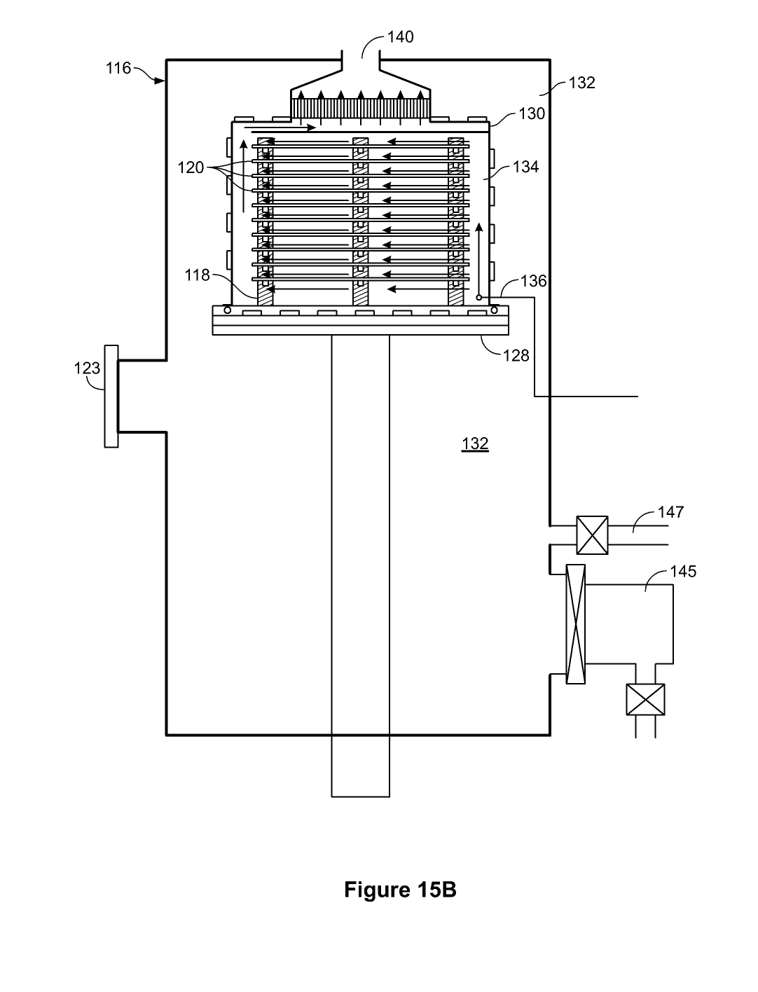

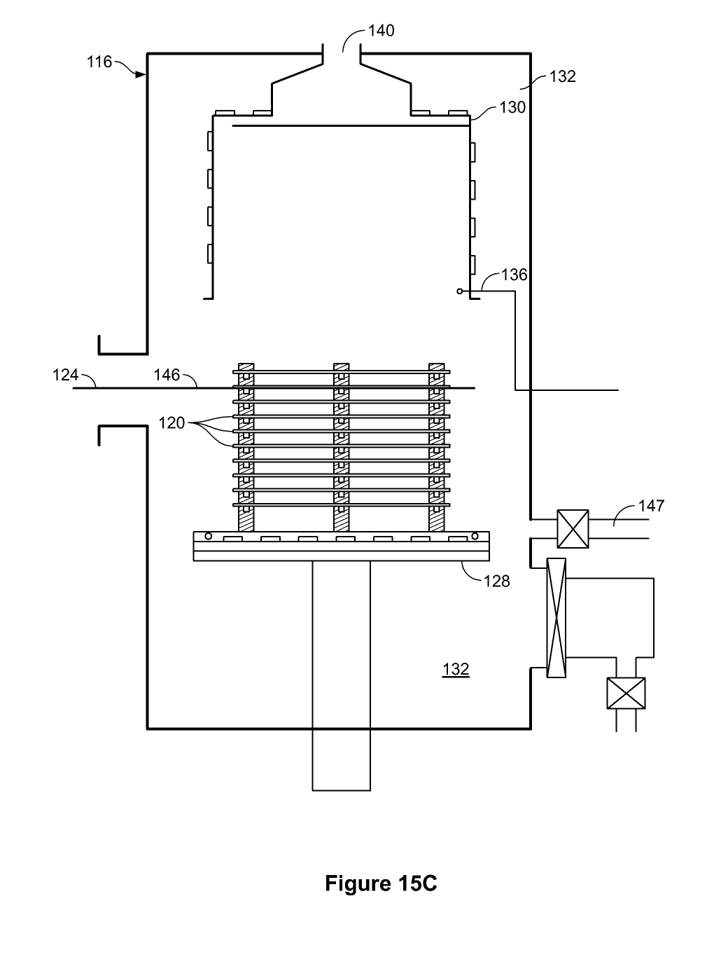

FIGS. 15A-15C show schematic cross sections of a batch process chamber useful for batch cluster tools like those of FIGS. 11-14. FIG. 15A shows a cross section of a portion of the process chamber including the reactor shell 130 and the platform 128. The reactor shell 130 and the platform, when closed, define the reaction space volume 134. Within the reaction space volume 134 is a boat 118 holding multiple substrates 120. Process vapors can be introduced to the reaction space volume 134 through one or more inlet line(s) 136. The boat 118, substrates 120, and line(s) 136 are arranged such that the process vapors flow parallel across each of the substrates 120 before exiting the reaction space volume 134 through an exhaust 140. The reactor shell 130 also has a baffle 138 to guide the flow of vapor process gases across the substrates 120. The reactor shell 130 can also have heaters 142 that can be used to heat the substrates 120 within the reaction space volume 134. The platform 128 is configured to engage with the reactor shell 130 with a gasket 144 to form the reaction space volume 134. The platform 128 can move down to lower position(s) for loading substrates 120 through the door 123 (FIG. 11). The platform 128 can move up to engage with the shell 130 after the substrates 120 are loaded to form a seal. After the platform 128 is engaged with the shell 130, process gases can be used to carry out desired processes on the substrates 120 followed by purging the reaction space 134. The substrates 120 can be removed after lowering the platform 128. In other implementations the reactor shell 130 can move, or the seal can be established by any combination of relative movement between the platform 128 and the shell 130.

FIG. 15B is a schematic cross section of the process chamber 116 with the reaction shell 130 sealed from the internal volume 132 of the process chamber 116. The process chamber exhaust 145 can be connected to a vacuum pump and used to remove any contaminants and decrease the pressure in the process chamber internal volume 132 after the chamber has been vented (such as for load/unload operations or after maintenance periods). The exhaust 140 from the shell can be used to remove contaminants and decrease the pressure in the reaction space volume 134. A throttled exhaust vent 147 can also be used for finer pressure control during operations, and can be connected to a separate vacuum pump. In some implementations the process chamber exhaust 145 and throttled exhaust vent 147 can be connected to different types of vacuum pumps. For example, the process chamber exhaust 145 can be connected to a roughing pump for achieving pressures between about 10 mTorr and atmospheric pressures. The exhaust vent 147 can be connected to a TMP pump for achieving pressures below 100 mTorr, such as 10⁻⁶ or 10⁻⁷ Torr.

FIG. 15C is a schematic cross section of the process chamber 116 with the platform 128 in a lowered position such that it is not engaged with the reactor shell 130. The door 123 (FIG. 11) between the transfer chamber 114 and process chamber 116 is shown as open. An end effector 146 of the transfer robot 124 (FIG. 11) is extended into the process chamber 116 to remove or load a substrate 120. As noted above, in some implementations the robot could have multiple paddles or end effectors to transfer multiple substrates at a time. In some implementations the robot could transfer racks or boats among chambers.

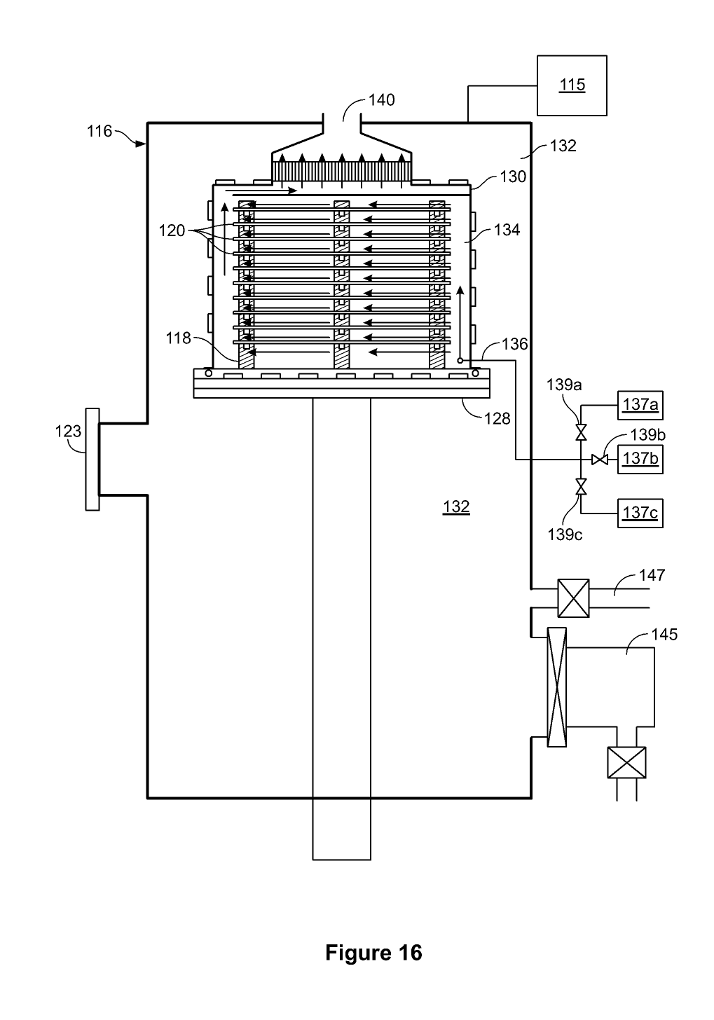

FIG. 16 shows a schematic cross section of an example of a batch process chamber, having connections to three different gas delivery systems configured for etching, atomic layer deposition (ALD) and self-assembled monolayer (SAM) deposition. In some implementations components of the process chamber 116 are connected to the controller 115 and reactants sources 137a, 137b, and 137c. The controller 115 can be configured to control the pressure and temperature in the process chamber 116 and reaction space volume 134 through exhausts 140, 145 and 147. The controller 115 can be configured to control valves 139a, 139b and 139c to supply process gases from the reactant sources 137a, 137b and 137c, respectively. The reactants sources 137a, 137b and 137c can each be gas delivery systems or subsystems configured to contain, meter and deliver reactant vapors used for the release etch, ALD layer formation, and SAM layer deposition.

The reactants sources 137a, 137b and 137c can contain reactive process gases and inert gases for purging the reaction space. The process controller 115 can be configured to perform the depositions of the ALD layer and SAM layer. For example, FIG. 8F shows an example of an IMOD having a cavity 19 and ALD layer 31a and SAM layer 31b formed within the cavity 19.

In some implementations the process chambers and reaction spaces can be used to etch a portion of the processed substrate. For example, the etch can be used for the release process. In some implementations a vapor phase etchant is used. In some implementations XeF₂ is vaporized and provided to the reaction space to etch portions of the substrate.

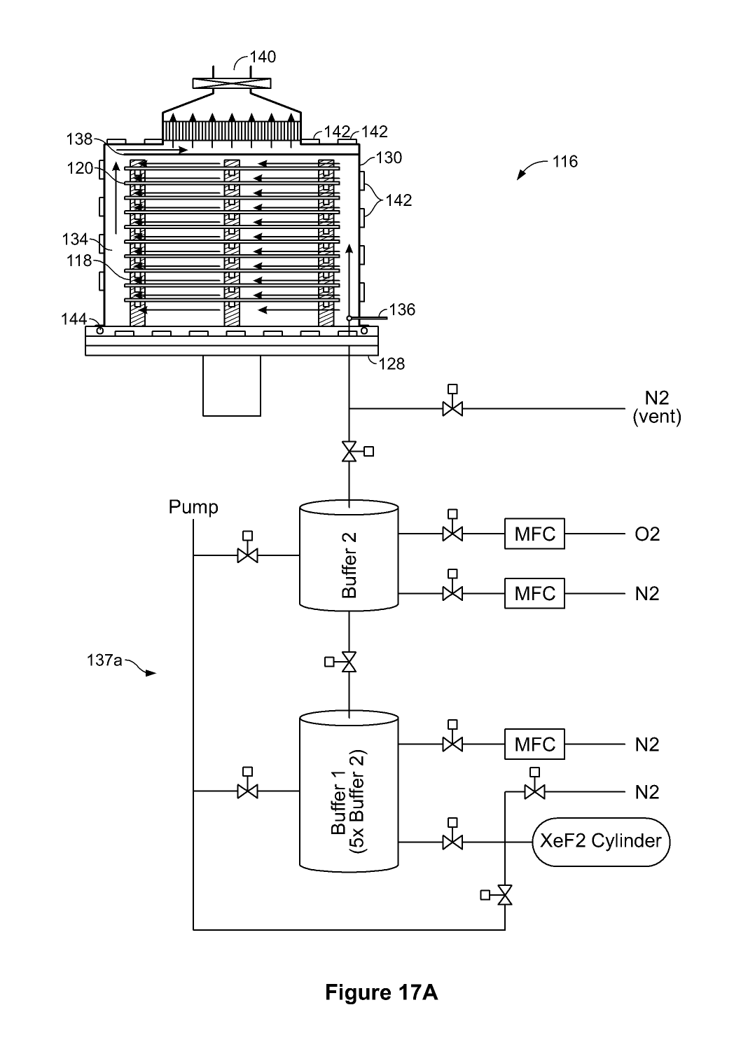

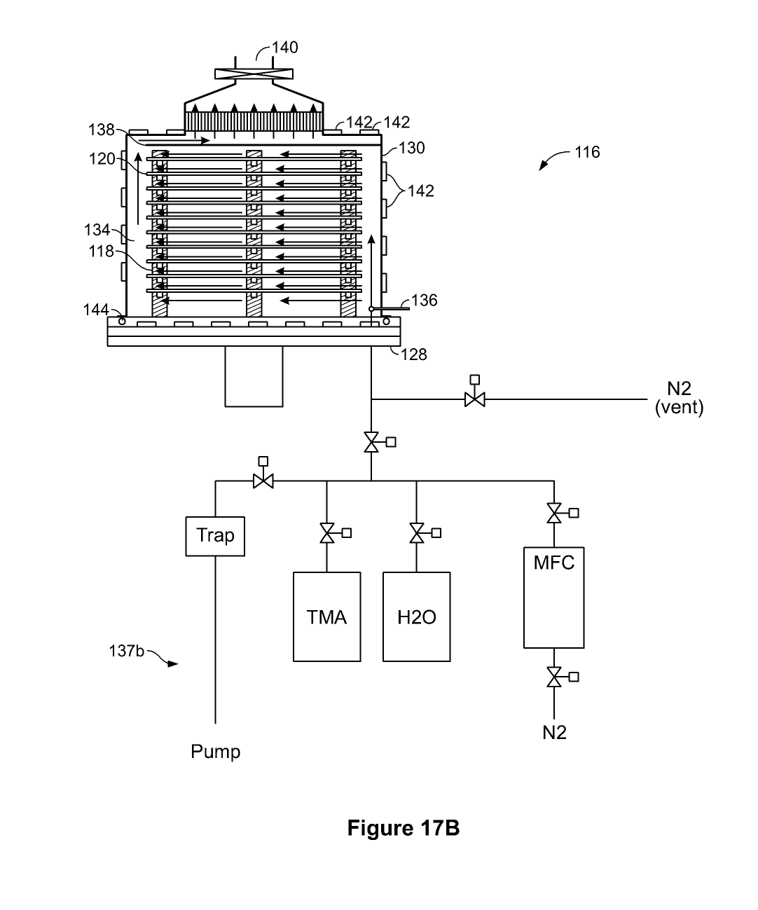

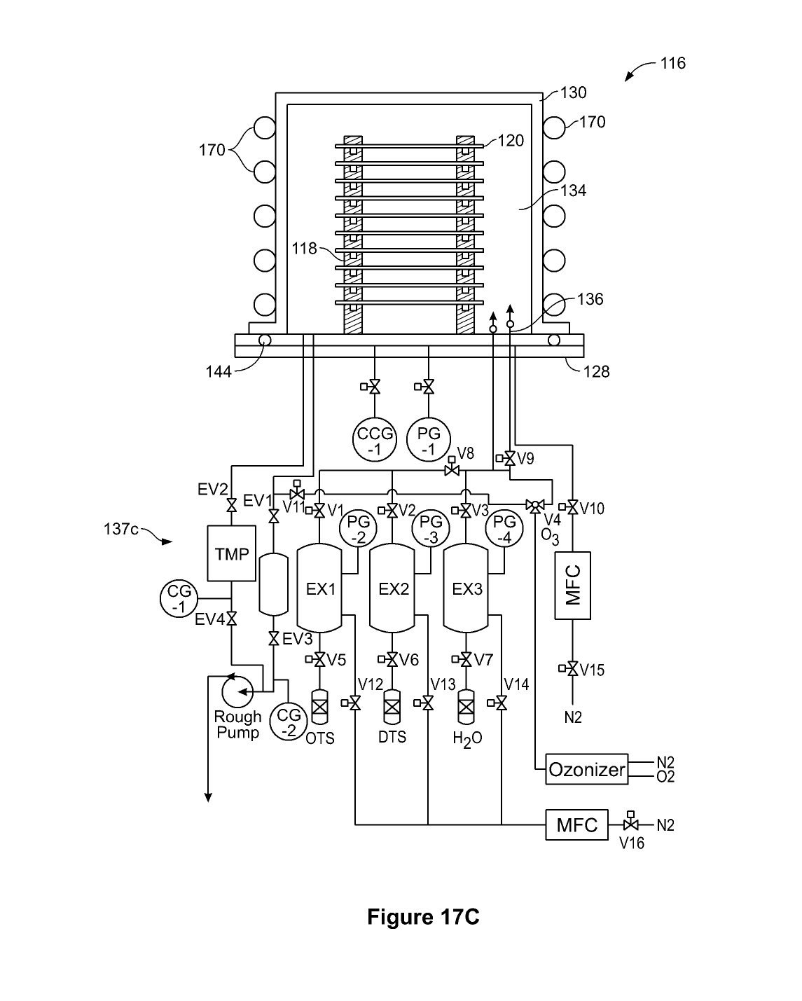

In some implementations the example of a batch process chamber 116 shown in FIG. 16 can be configured to perform the release etch. The reactant source 137a can be a vapor delivery system or subsystem configured to contain, meter and deliver an etchant such as XeF₂ or XeF₂ combined with a buffer to achieve a desired concentration of XeF₂. The reactant source 137a can additionally provide an inert gas, such as nitrogen for purging the reaction space after the release etch is completed. In some implementations the controller 115 is configured to open the valve 139a to supply XeF₂ to the batch substrates to perform the etch release. The controller 115 can also be configured to provide an inert gas to purge the reaction space after etching has proceeded sufficiently long to remove the sacrificial layer and form the cavity between electrodes of the electromechanical system devices. Further details of an example of a gas delivery system that can be used for the reactant source 137a for conducting release etching is illustrated and described with respect to FIG. 17A below.

In some implementations the batch process chamber 116 shown in FIG. 16 can be configured to deposit the ALD layer. The reactant source 137b can be a gas delivery system or subsystem configured to contain an aluminum source vapor such as TMA, an inert or purge gas, and an oxygen source vapor such as water. In some implementations the controller 115 is programmed to open the valve 139b to saturate the batch substrates with adsorbed TMA, followed by purging of the reaction space 134, followed by supplying water the batch substrates to react with adsorbed TMA, followed again by providing an inert gas to purge the reaction space. The controller 115 can be configured to repeat the sequence of providing TMA, purging, providing water, and purging to form an aluminum oxide having a desired thickness. Further details of an example of a gas delivery system that can be used for the reactant source 137b for conducting ALD is illustrated and described with respect to FIG. 17B below.

In some implementations the batch process chamber 116 shown in FIG. 16 can be configured to deposit the SAM layer. The reactant source 137c can be configured to contain an SAM monomer such as n-decyltrichlorosilane. In some implementations the controller 115 is configured to open the valve 139c to supply n-decyltrichlorosilane to the batch substrates. In some implementations multiple SAM monomers can be supplied to the reactor. The reactant source 137c can also be configured to contain an oxygen source vapor such as oxygen and can also include an excited species generator. The reactant source 137c can be additionally be configured to contain an inert gas, such as nitrogen for purging the reaction space after the SAM layer is formed. In some implementations the controller 115 is configured to generate ozone or oxygen plasma to clean the reaction space after the substrates have been removed. Further details of an example of a gas delivery system that can be used for the reactant source 137c for conducting SAM deposition is illustrated and described with respect to FIG. 17C below.

FIG. 17A is a schematic illustration of an example of a batch process chamber configured for release etching. The batch process chamber 116 can be configured with the reactor shell 130, platform 128 and related components as described above with respect to FIGS. 15A-15C. The batch process chamber 116 is a module or tool that includes a reactant source 137a in the form of a gas delivery system for providing an etchant to the reaction space 134 defined by the reactor shell 130 and platform.

The etchants chosen and the form of the reactant source 137a depend upon the sacrificial material employed in the fabrication of electromechanical systems devices. Fluorine-based etchants, such as XeF₂, can selectively etch certain metallic and semiconductor sacrificial materials, such as tungsten (W), molybdenum (Mo) or silicon, without removing other exposed materials in an electromechanical systems device, such as silicon oxide, aluminum oxide and aluminum. The illustrated implementation includes a vessel holding solid XeF₂ crystals and gas lines, valves, buffers and gas sources configured to vaporize and deliver etchant vapor to the reaction space 134. In particular, vapor and inert carrier gas (such as the illustrated nitrogen or N₂ gas) are drawn into Buffer 1, which serves as an expansion chamber to aid vaporization of the XeF₂ crystals. The pressure in Buffer 1 is reduced by way of a pump. Buffer 1 can periodically feed vaporized XeF₂ to Buffer 2, which has a smaller volume than Buffer 1, in which co-etchants (such as the illustrated oxygen or O₂ gas) and inert carrier gases can be mixed before being fed to the reaction space 134. The cluster tool's controller 115 (FIG. 11) can include programming to conduct the etch release process as described.

In some implementations the pressure in the etch reaction space 134 during processing is from about 0.1 to about 5 Torr. In some implementations the release etch takes from about 10 minutes to about 60 minutes for the removal of sacrificial material (such as molybdenum) from a batch of substrates. The exhaust 140 from the reaction space 134 can be closed off after the target pressure is reached, and remain closed after etching reactant vapors are provided from the reactant source 137a. The substrates can soak in the backfilled reaction space 134 until the etchants are exhausted, in which case another cycle of vaporization and backfill can be conducted, or until the sacrificial material is fully etched.

In some implementations the parts defining the reaction space 134 of the release etch process chamber 116, such as the reactor shell 130, the platform 128 and the rack 118, are constructed out of materials that are resistant to XeF₂-based etchants and any reaction by-products, such as aluminum oxide and quartz. XeF₂ can react with water to form corrosive compounds such as HF that can undesirably etch the substrate and reaction space materials. The cluster tool can be operated to minimize the risk of water contamination of the etch process chamber, such as from neighboring ALD process chambers and SAM chambers as described below, to avoid formation of undesirable by-products.

FIG. 17B is a schematic illustration of portions of an example of a batch process chamber configured for ALD. The batch process chamber 116 can be configured with the reactor shell 130, platform 128 and related components as described above with respect to FIGS. 15A-15C. The batch process chamber 116 is a module or tool that includes a reactant source 137b in the form of a gas delivery system for providing ALD reactants and purge gas to the reaction space 134 defined by the reactor shell 130 and platform.

The reactants and the form of the reactant source 137b depend upon the desired material to be deposited. The illustrated implementation includes a vessel holding a metal reactant, such as trimethyl aluminum (TMA, (CH₃)₃Al) and an oxygen source vapor, such as water. The TMA and water can be delivered to the reaction space by alternate and sequential pulses by high speed valves, with intervening removal of reactants from the reaction space 134, such as by providing an inert gas to purge the reactor of the previous reactant. As TMA is naturally liquid, the vessel can also serve as a vaporizer, such as a bubbler. The TMA can adsorb on surfaces of the batch of substrates in one reactant pulse, and the water can react with the adsorbed species in a subsequent pulse to form a self-limited monolayer of aluminum oxide. In some implementations the reactants flow through the reaction space 134 to the reaction space's exhaust 140; in some implementations, the exhaust 140 is closed and the reaction space 134 backfilled in one or more of the reactant pulses. Multiple cycles can be performed to form an aluminum oxide layer having a desired thickness. In some implementations, the aluminum oxide layer has a thickness of about 3 Å to about 50 Å. In some implementations, the aluminum oxide layer has a thickness of about 40 Å to about 90 Å. In some implementations the aluminum oxide layer can be used as a seed layer to promote the subsequent formation of the SAM. The cluster tool's controller 115 (FIG. 11) can include programming to conduct the ALD process as described.

In some implementations the pressure in the reaction space during the ALD process is from about 100 mTorr to about 1 Torr. In some implementations the deposition of the ALD layer or seed layers takes between about 10 and 80 minutes.

In some implementations multiple process gas inlets can be used with the reaction space to avoid mixing the process gases in the inlet lines.

In some implementations the ALD reaction space is made of a material that is resistant to TMA, water, and any reaction by-products, such as quartz, titanium and/or aluminum oxide. In some implementations the reaction space is periodically cleaned to remove aluminum oxide formed on the reaction space surfaces.

FIG. 17C is a schematic illustration of portions of an example of a batch process chamber configured for SAM deposition. The batch process chamber 116 can be configured with similar reactor shell 130, platform 128 and related components to those described above with respect to FIGS. 15A-15C. Unlike the previously described implementations, the illustrated batch process chamber 116 includes infrared (IR) heaters 170 around the shell 130, and the shell can be at least partially transparent to IR light. In some implementations an electric heater can be used for heating the process chamber configured for SAM deposition. The batch process chamber 116 is a module or tool that includes a reactant source 137c in the form of a gas delivery system for providing monomers capable of forming self-assembled monolayers (SAMs).

The illustrated implementation of the reactant source 137c includes a vessel for providing vapor phase monomer n-decyltrichlorosilane (DTS), a vessel holding water, expansion chambers for vaporizing each of these sources, inert carrier gas provided to the expansion chambers, and a source of ozone for post-deposition cleaning of the reaction space 134 defined by the shell 130 and the platform 128.

In some implementations a process chamber with a reaction space for forming a SAM can be used as part of the batch cluster tool. In some implementations a monomer for forming a SAM is used. The monomer can be an organic linear chain molecule having a hydrophobic tail and hydrophilic tail. In one implementation n-decyltrichlorosilane (DTS) and water are used to form the SAM. In some implementations the pressure in the reaction space when depositing SAMs is between about 100 mTorr and about 1 Torr. In some implementations depositing the SAMs takes between about 10 and about 90 minutes.

In some implementations the SAM reaction space can be cleaned using ozone or other reactive cleaner to prevent buildup on the walls of the reaction space. The cleaning can be performed in between processing of a batch of substrates or periodically after processing multiple batches of substrates. In some implementations ozone can be used for cleaning the surface of the ALD layer or other seed layer to remove any contaminants, such as hydrocarbons. Hydrocarbon contamination can be caused by exposure to a clean room atmosphere or breaking vacuum, or in some implementations can result from the ALD process if organic precursors are employed. The cluster tool's controller 115 (FIG. 11) can include programming to conduct the SAM deposition process as described, including any post-deposition cleaning.

An example of a suitable material for the reaction space for resistance to the post-deposition or periodic cleaning process is aluminum oxide, also known as alumina. In some implementations the SAM reaction chamber and/or process chamber can be lined with or coated with an anodized aluminum liner capable of resisting corrosion from HCl and any other by-products formed during the deposition of the SAM. In some implementations the SAM reaction chamber is resistant to ozone. In some implementations the liner can be made of sapphire, or single crystal alumina.

The process chambers and reaction spaces can be constructed of different materials based on the reactor configurations and process gases that are used. In some implementations the reaction space shell can be made out of quartz. In some implementations an IR heater can be used with a quartz or sapphire reaction space shell, particularly in implementations subject to highly oxidizing environments, such as the SAM batch process tool, in which activated oxygen species like ozone can be employed for post-deposition cleaning of the chamber. In some implementations the reaction space shell can be made out of stainless steel, titanium or aluminum. Such metal shells can include surface coatings or liners to better withstand processing associated with, for example, the release etch and ALD processes and any periodic cleaning processes for them. In some implementations the shell can be anodized aluminum, include an anodized aluminum liner or be coated with alumina. In some implementations the reaction space shell in the etch process chamber can be made out of aluminum or anodized aluminum. In some implementations the reaction space shell in the ALD process chamber can be made out of aluminum, quartz, or anodized aluminum. In some implementations the reaction space shell in the SAM process chamber can be made out of quartz, or anodized aluminum. Aluminum reactor walls can be obtained, for example, from S.U.S. Cast Products, Inc. of Logansport, Ind.

After the release/etch, the partially fabricated devices are sensitive to contaminants. For example, exposing the partially fabricated device to a clean room after the release and before the formation of the ALD layer and SAM layer can result in carbon contamination or other contaminants in the cavity that can degrade the properties of the finished IMOD device. The risk of contamination of the partially fabricated device can be lowered by handling the substrates at a reduced pressure and handling the substrates in a closed environment, such as the batch cluster tools 110, 150, 160, and 170 described above with respect to FIGS. 11-14, which can be operated at low pressures. For example, the release/etch process, ALD layer deposition, and SAM formation can all be performed in such batch cluster tools. The substrates can be kept within the vacuum environment without being exposed to the clean room atmosphere until after the antistiction layer, e.g. ALD and SAM, is formed within the cavity, thereby decreasing the likelihood of contamination of the partially fabricated device. Additionally, conducting all three processes of release, ALD and SAM deposition within the same tool decreases the amount of substrate handling post-release, when the devices are sensitive to damage.

In some implementations during processing the pressure in the reaction space 134 is greater than the pressure in the process chamber 116 and transfer chamber 114, and the pressures in the process chamber 116 and transfer chamber 114 can be roughly the same. In some implementations when transferring substrates the transfer chamber 114 pressure is greater than the pressure in the process chamber 116 and reaction space 134. In some implementations the pressure in the reaction space 134 is lowered before the reaction space 134 is opened to the process chamber 116. In some implementations the pressure in the reaction space volume 134 during processing is greater than about 10⁻² Torr, while the pressure in the process chamber 116 and transfer chamber 114 when transferring substrates is less than about 10⁻⁴ Torr. In some implementations the pressure in the process chamber 116 and transfer chamber 114 when transferring substrates is less than about 10⁻⁷ Torr. In some implementations the pressure in the process chambers and transfer chamber when transferring substrates can be between about 10⁻⁵ Torr and 10⁻⁸ Torr. In some implementations transferring the substrates includes transferring the substrates from a source chamber to a destination chamber, wherein the source and destination chambers and any chamber in between the source and destination chambers are maintained at a pressure of less than 10⁻⁵ Torr during transferring.

The reaction space, for example reaction space volume 134, can be purged after a batch is processed therein to remove any process gases and by-products from the reaction space. An inert gas can be used as a purge gas to displace any reactive process vapors and volatile by-product remaining in the reaction space after processing the substrates. In some implementations, a vacuum pump can be used to decrease the pressure in the reaction space prior to opening the reactor space to the surrounding process chamber space.

It is faster to pump down the smaller volume of the reaction space 134 than it is to pump down the larger internal volume 132 of the process chamber 116. The internal volume 132 of the process chamber 116 can be maintained at a lower pressure than the processing pressure used in the reaction space 134 during processing. Thus, the time to reduce the pressure in the reaction space 134 prior to opening the shell 130 and unloading the substrates is shortened in comparison to the time that it would take to reduce the pressure in the larger process chamber internal volume 134. The transfer chamber 114 can also be maintained at pressure similar to the pressure used in the process chamber 116.

The process gases used in the different processes, such as the etch/release, ALD layer formation and SAM formation, can react together to form undesired by-products and/or be incompatible with the materials used for the reaction space and process chambers that perform the other processes. Purging of the reaction spaces can reduce the risk of cross contamination and avoid the formation of undesirable by-products formed by mixing process gases used in the different processes.

In another implementation the transfer chamber 114 can be maintained at a higher pressure than the internal volumes 132 of the process chambers 116 and the reaction spaces 134. An inert gas, such as nitrogen, can be provided to the transfer chamber 114 to maintain a pressure higher than the process chambers. The positive pressure in the transfer chamber 114 can prevent diffusion or the flow of gases from the process chamber to the transfer chamber to decrease the likelihood of cross contamination of process gases between the different process chambers and reaction spaces. Unlike the opposite pressure gradient, which can prevent flow into the reaction spaces, employing a higher pressure in the transfer chamber 114 can prevent interaction between residual process gases of different processes and thus prevent cross-contamination. In some implementations a high vacuum (low pressure) is used in the transfer chamber, process chamber, and reaction space. The high vacuum pressure can result in decreased molecules in the chambers and decrease the chance of cross contamination because of the lower numbers of molecules present in the chambers.

In some implementations the batch cluster tool can be used to process multiple substrates simultaneously, and to sequentially perform release/etch, ALD of an antistiction layer, and vapor deposition of antistiction SAM. An example of sequential processing will be described with reference to FIG. 12 for describing movement among the chambers of a batch cluster tool 150, along with reference to FIG. 15B for describing parts of individual process chambers. Multiple substrates can be loaded into a load lock chamber 153. The substrates can be transferred from the load lock chamber 153 into transfer chamber 151 and into a first processing chamber 154a by the robot 152. The robot 152 can transfer one or more substrates at a time. After multiple substrates are loaded in the first process chamber 154a, the platform 128 can be engaged with the reactor shell 130 to form the reaction space 134 inside the first process chamber 154a. The multiple substrates can be exposed to an etchant, such as XeF₂, to etch a portion of the substrates to form a cavity, for example 19 (FIG. 8E). After etching the substrates, a purge gas can be used to purge the reaction space 134 followed by the use of a vacuum pump to decrease the reaction space pressure to a pressure that can be about the same as the pressure in the surrounding process chamber interior volume 132. The platform 128 can be lowered and the substrates can be transferred from the first process chamber 154a into the transfer chamber 151 and into a second process chamber 154b by the transfer robot 152. After the substrates are transferred out of the first process chamber 154a, a new batch of substrates can be transferred into the first process chamber 154a and processed.

After the substrates can be transferred into the second process chamber 154b, the platform 128 in the second process chamber 154b can be raised to engage with the reactor shell 130 in the second process chamber 154b. An ALD process can be conducted therein. For example a metal source vapor and an oxidant source vapor can be alternated to form an antistiction layer in the cavity left by the release/etch by ALD. In one implementation, TMA and water can be alternately and sequentially supplied to the multiple substrates to form aluminum oxide within the cavity formed during the etch process. The pulses of TMA and water can be separated by purge periods of flowing inert purge gas. After formation of the aluminum oxide layer the reaction space can be purged and a vacuum pump can be used to decrease the pressure in the reaction space to a pressure that can be about the same as the pressure in the surrounding process chamber. The platform 128 can be lowered and the substrates can be transferred from the second process chamber 154b into the transfer chamber 151 and into a third process chamber 154c by the transfer robot 152. After the substrates are transferred out of the second process chamber 154b, a new batch of substrates can be transferred into the second process chamber 154b and processed.

After the substrates are transferred into the third process chamber 154c, the platform 128 in the third process chamber 154c is raised to engage with the reactor shell 130 in the third process chamber 154c. An antistiction self-assembled monolayer (SAM) can be formed in the third chamber 154c over the antistiction layer left by the ALD process. In one implementation N-decyltrichlorosilane and water can be used to form the SAM layer on the aluminum oxide layers formed in the cavities on the substrates. After formation of the SAM the reaction space can be purged and a vacuum pump can be used to decrease the pressure in the reaction space 134 to a pressure that is about the same as the pressure in the surrounding process chamber interior volume 132. The platform 128 can be lowered and the substrates can be transferred from the third process chamber 154c into the transfer chamber 151 and into the load lock chamber 153 or another process chamber for further processing. After the substrates are transferred out of the third process chamber 154c, a new batch of substrates (such as from the second process chamber 154b) can be transferred into the third process chamber 154c and processed.

FIG. 8F shows an example of an IMOD having a cavity 19 with an ALD layer 31a and a SAM layer 31b lining all surfaces of the cavity 19.

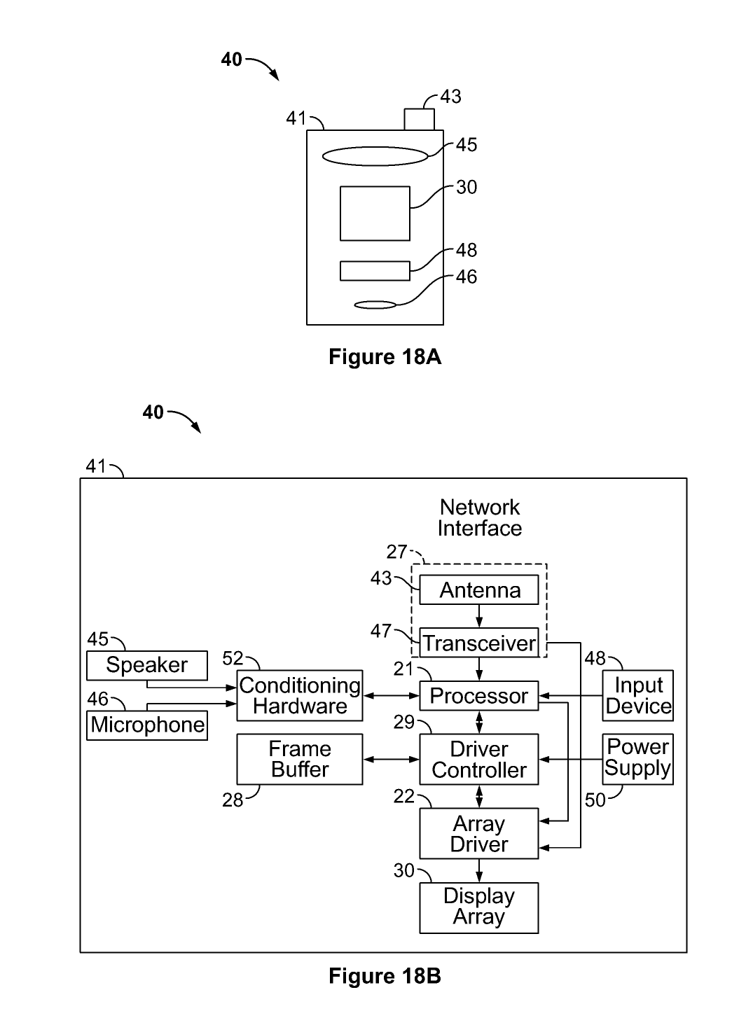

FIGS. 18A and 18B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), NEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. In some implementations the methods illustrated in FIGS. 9 and 10 can be implemented in software and stored on or transmitted over as one or more instructions or code on a computer-readable medium that can be associated with a controller, such as the controller 115 of FIG. 11. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product. Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of forming a device, comprising:
transferring a batch of substrates from a transfer chamber of a batch cluster tool into an etch chamber of the batch cluster tool;
exposing the substrates to a vapor phase etchant; and
after exposing the substrates to a vapor phase etchant, performing at least one of:
transferring the substrates through the transfer chamber and into an atomic layer deposition (ALD) chamber and exposing the substrates to vapor phase reactants to form a thin film on the substrates by ALD, and
transferring the substrates through the transfer chamber and into a third chamber and exposing the substrates to vapor phase reactants to form a self-assembled monolayer (SAM) on the substrates.

2. The method of claim 1, wherein the thin film is formed on the substrates by ALD and the SAM is formed on the substrates.

3. The method of claim 1, wherein transferring a batch includes sequential single substrate transfer or a batch transfer.

4. The method of claim 1, wherein the processing pressure of at least one of the etch, ALD, and SAM processes is different from the transfer pressure.

5. The method of claim 1, wherein transferring the substrates includes transferring the substrates from a source chamber to a destination chamber, wherein the source and destination chambers and any chamber in between the source and destination chambers are maintained at a pressure of less than 10⁻⁵ Torr during transferring.

6. The method of claim 7, wherein the cluster tool is configured to handle rectangular substrates.

7. A method for forming an electromechanical systems device, comprising:
removing sacrificial layers to create gaps between movable electrodes and stationary electrodes of electromechanical devices on multiple substrates in a first batch process chamber of a cluster tool; and
performing at least one of:
depositing atomic layer deposition (ALD) layers within the gaps of the substrates in a second batch process chamber of the cluster tool by atomic layer deposition, and
depositing self-assembled monolayers (SAMs) within the gaps of the substrates in a third batch process chamber of the cluster tool.

8. The method of claim 7, wherein removing the sacrificial layers includes providing XeF₂ to the first batch process chamber of the cluster tool while maintaining a pressure in the first batch process chamber of the cluster tool between about 0.1 and about 5 Torr.

9. The method of claim 7, wherein ALD layers are formed within the gaps of the substrates in the second batch process chamber of the cluster tool, and the self-assembled monolayers (SAMs) are deposited over the ALD layers within the gaps of the substrates in the third batch process chamber of the cluster tool.

10. The method of claim 9, wherein each of removing the sacrificial layers, depositing ALD layers, and depositing the SAMs are conducted at pressures greater than 10⁻² Torr while a transfer chamber of the cluster tool connected to each of the process chambers is maintained at a pressure less than 10⁻⁴ Torr when transferring substrates among the transfer chamber and each of the processing chambers.

11. The method of claim 9, wherein depositing ALD layers includes providing trimethyl aluminum (TMA) and water in alternate and sequential pulses to the second batch process chamber of the cluster tool to deposit aluminum oxide ALD layers wherein depositing ALD layers includes establishing pressure in the second batch process chamber between about 100 mTorr and about 1 Torr.

12. The method of claim 9, wherein depositing SAMs includes providing n-decyltrichlorosilane to the third batch process chamber of the cluster tool wherein depositing SAMs includes establishing pressure in the third batch process chamber between about 100 mTorr and about 1 Torr.

13. The method of claim 9, wherein removing the sacrificial layers takes between about 10 and about 60 minutes, depositing the ALD layers takes between about 10 and 80 minutes, and depositing the SAMs takes between about 10 and about 90 minutes.

14. An apparatus for processing electromechanical systems devices, comprising:
a first processing chamber configured to process multiple substrates, wherein the first processing chamber is in fluid communication with an etchant source including a fluorine based etchant;
one or more of:
a second processing chamber configured to process multiple substrates, wherein the second processing chamber is in fluid communication with a first source including an oxidizing source and a second source including one of a semiconductor and a metal source, and
a third processing chamber configured to process multiple substrates, wherein the third processing chamber is in fluid communication with an organic source chemical; and
a transfer chamber selectively communicating with each of the first, and second or third processing chambers, wherein the transfer chamber includes a robot configured to transfer substrates among the transfer chamber and first, and second or third processing chambers.

15. The apparatus of claim 14, wherein the apparatus includes the second processing chamber and the third processing chamber.

16. The apparatus of claim 15, further including a control system in communication with the second processing chamber for alternatingly switching between the first source and the second source.

17. The apparatus of claim 14, wherein the third processing chamber has an anodized liner capable of resisting corrosion from HCl.

18. The apparatus of claim 15, further includes at least one vacuum pump in fluid communication with each of the transfer chamber and first, second, and third processing chambers.

19. The apparatus of claim 14, wherein the robot is configured to sequentially transfer multiple single substrates or to transfer multiple substrates simultaneously in a batch transfer.

20. The apparatus of claim 14, wherein the batch cluster tool is configured to handle rectangular substrates having an area greater than the area of rectangular substrate with dimensions of about 370 mm by about 470 mm.

21. The apparatus of claim 14, wherein the fluorine based etchant is XeF₂, the metal source is trimethyl aluminum, the oxidizing source is water, and the organic source chemical is n-decyltrichlorosilane.

22. The apparatus of claim 14, wherein the first processing chamber is made of a material that is resistant to XeF₂-based etchants.

23. The apparatus of claim 14, wherein the apparatus includes two or more of one of the first, second, and third processing chambers.

24. The apparatus of claim 23, wherein the apparatus includes two or more of the first and third processing chambers.

25. A batch cluster tool for processing electromechanical systems devices, comprising:
a first processing chamber configured to process multiple substrates, including means for removing sacrificial layers from the substrates;
one or more of:
a second processing chamber configured to process multiple substrates, including means for forming an ALD layer on the substrates, and
a third processing chamber configured to process multiple substrates, including means for forming a self-assembled monolayer on the substrates; and
a transfer chamber capable of selectively communicating substrates among the first, second, and third processing chamber, including means for transferring substrates between chambers of the first, second, and third processing chambers.

26. The apparatus of claim 25, wherein the apparatus includes both the second processing chamber and the third processing chamber.

27. The apparatus of claim 25, wherein the apparatus includes two or more first processing chambers, two or more second processing chambers, and two or more third processing chambers.

28. The apparatus of claim 25, wherein the batch cluster tool is configured to handle rectangular substrates.
